(19) United States
(12) Patent Application Publication
(10) Pub. No.: US 2026/0087016 A1
(43) Pub. Date: Mar. 26, 2026

(54) LOW LATENCY USER DIRECTED MARKET GENERATION

(71) Applicant: FanDuel Limited, Edinburgh (GB)

(72) Inventors: Stefan Borjesson, Porto (PT); Catherine Everett, Hoboken, NJ (US); Michael Barber, Acworth, GA (US); Jonathon Carter, Leeds (GB)

(21) Appl. No.: 19/410,174

(22) Filed: Dec. 5, 2025

Related U.S. Application Data
(63) Continuation-in-part of application No. 18/893,423, filed on Sep. 23, 2024.

(51) Int. Cl. G06F 16/2455; G06F 16/2452; G06F 30/20; G06F 40/205; G06Q 30/0201

(52) U.S. Cl. CPC G06F 16/24553; G06F 16/24522; G06F 30/20; G06F 40/205; G06Q 30/0206

(57) ABSTRACT

Systems, methods, and computer-readable media for providing low-latency markets for wagering on sporting events are disclosed. In some embodiments, an outcome matrix may be generated by a plurality of contest simulations utilizing statistical data of a history of sporting events. Outcome data of the outcome matrix may be indicative of probabilities of events occurring during an upcoming contest. The probabilities may be calculated, and markets may be priced based on the calculated probabilities. The priced markets may be provided to users by a graphical user interface by user computing device. Furthermore, users may request user-requested markets by inputting different markets into the GUI. The user-requested markets may then be priced using the outcome data of the outcome matrix and stored calculations thus, providing new markets based on the user-requested markets from the outcome matrix without generating new simulations.

### RELATED APPLICATIONS

This patent application is a continuation-in-part application claiming priority benefit, with regard to all common subject matter, of U.S. patent application Ser. No. 18/893,423, filed Sep. 23, 2024, and entitled “LOW LATENCY USER DIRECTED MARKET GENERATION” (“the '423 Application”). The above-referenced patent application is hereby incorporated by reference in its entirety into the present application.

### BACKGROUND

### 1. Field

Embodiments of the present disclosure relate to generating market pricing for sports wagers. Specifically, embodiments of the present disclosure relate to generating user-requested markets from an outcome matrix and associated stored calculation tables.

### 2. Related Art

Bettors have been wagering on contests for many years. Bettors tend to place similar, popular wagers on contests (e.g., sports), such as wagering on the outcome, the point spread, and the like. However, as betting proliferates and bettors become increasingly prolific, a desire for a more personalized wagering experience has emerged.

Typically, wagerable sports markets are dictated by entities responsible for evaluating upcoming contests, providing markets, and managing liability for those markets. Typically, these markets are unchanging or only change when in reaction to large quantities of betting data provided by large numbers of bettors. The markets are predetermined selections and lines that are provided to the user, and these markets are the only options that bettors have. There is typically no customization provided to the user, as it would has previously not been possible for the entities to price markets in real time while maintaining liability and risk management. What is needed are methods, systems, and media for providing low-latency, customizable markets to users while maintaining risk and liability management.

### SUMMARY

Embodiments of the present disclosure solve the above-mentioned problems by providing systems, methods, and computer-readable media for generation of customized markets based on user preferences and user requests.

In some aspects, the techniques described herein relate to one or more non-transitory computer-readable media storing computer-executable instructions that, when executed by at least one processor, perform a method of generating markets for making wagers on a contest based on user requests, the method including: obtaining data indicative of past contests; running a contest simulation including a plurality of simulations of the contest; storing outcome data in an outcome matrix, wherein the outcome data is indicative of probabilities of one or more live events occurring during the contest; pricing markets based on the probabilities of the one or more live events occurring during the contest; causing display of the markets to a user by a user computing device; receiving a user-requested market from the user computing device; generating a query indicative of the user-requested market; selecting, by the query, a set of outcome data from the outcome matrix and equations for pricing the user-requested market; calculating alternative probabilities for the user-requested market based on the set of outcome data and the equations; pricing the user-requested market based at least in part on the alternative probabilities; and causing display of the user-requested market by the user computing device.

In some aspects, the techniques described herein relate to a media, wherein the contest simulation includes a Monte Carlo algorithm running at least 10,000 simulations of the contest.

In some aspects, the techniques described herein relate to a media, wherein the contest is one of a plurality of contests, wherein the method further includes providing a single structure of the outcome matrix for the plurality of contests.

In some aspects, the techniques described herein relate to a media, wherein the plurality of contests includes different sports.

In some aspects, the techniques described herein relate to a media, wherein the method further includes placing pricing limitations on the user-requested market based on the alternative probabilities or a potential payout.

In some aspects, the techniques described herein relate to a media, wherein the user-requested market exceeds the pricing limitations, wherein the method further includes: denying the user-requested market based on the pricing limitations; and recommending at least one alternative market to the user by the user computing device.

In some aspects, the techniques described herein relate to a media, wherein the user-requested market includes a plurality of user-requested markets, wherein the method further includes: calculating individual probabilities of the one or more live events occurring for each market of the plurality of user-requested markets; generating a total market including a plurality of new markets, each new market of the plurality of new markets based on the individual probabilities of the one or more live events occurring for the plurality of user-requested markets; and causing display of the total market by the user computing device.

In some aspects, the techniques described herein relate to a media, wherein the method further includes: receiving update data indicative of at least one occurrence in at least one of the one or more live events; rerunning the contest simulation based on the update data; and storing updated outcome data in the outcome matrix.

In some aspects, the techniques described herein relate to a system for generating markets for making wagers on a contest based on user requests, the system including: at least one processor; one or more databases storing data indicative of statistics relating to historical sporting contests; and one or more non-transitory computer-readable media storing computer-executable instructions that, when executed by the at least one processor, perform a method of generating the markets for making the wagers on the contest based on the user requests, the method including: obtaining contest data indicative of past contests from the one or more databases; running a contest simulation including a plurality of simulations of the contest; storing outcome data in an outcome matrix, wherein the outcome data is indicative of probabilities of events occurring during the contest; pricing markets based on the probabilities of the events occurring during the contest; causing display of the markets to a user by a user computing device; receiving a user-requested market from the user computing device; generating a query indicative of the user-requested market; selecting, by the query, a set of outcome data from the outcome matrix and equations for pricing the user-requested market; calculating alternative probabilities for the user-requested market based on the set of outcome data and the equations; pricing the user-requested market based at least in part on the alternative probabilities; and causing display of the user-requested market by the user computing device.

In some aspects, the techniques described herein relate to a system, wherein the contest simulation includes a Monte Carlo algorithm running at least 10,000 simulations of the contest.

In some aspects, the techniques described herein relate to a system, wherein the contest is one of a plurality of contests, wherein the method further includes providing a single structure of the outcome matrix for the plurality of contests.

In some aspects, the techniques described herein relate to a system, wherein the plurality of contests includes different sports.

In some aspects, the techniques described herein relate to a system, wherein the method further includes placing pricing limitations on the user-requested market based on the alternative probabilities or a potential payout.

In some aspects, the techniques described herein relate to a system, wherein the user-requested market exceeds the pricing limitations, wherein the method further includes: denying the user-requested market based on the pricing limitations; and recommending at least one alternative market to the user by the user computing device.

In some aspects, the techniques described herein relate to a system, wherein the user-requested market includes a plurality of user-requested markets, wherein the method further includes: calculating individual probabilities of the events occurring for each market of the plurality of user-requested markets; generating a total market including a plurality of new markets each new market of the plurality of new markets based on the individual probabilities of the events occurring for the plurality of user-requested markets; and causing display of the total market by the user computing device.

In some aspects, the techniques described herein relate to a method of generating markets for making wagers on a contest based on user requests, the method including: obtaining data indicative of past contests; running a contest simulation including a plurality of simulations of the contest; storing outcome data in an outcome matrix, wherein the outcome data is indicative of probabilities of events occurring during the contest; pricing markets based on the probabilities of the events occurring during the contest; causing display of the markets to a user by a user computing device; receiving a user-requested parlay from the user computing device, wherein the user-requested parlay includes a plurality of user-requested markets; generating a query indicative of the user-requested parlay; selecting, by the query, a set of outcome data from the outcome matrix and equations for pricing the user-requested parlay; calculating alternative probabilities for the user-requested parlay based on the set of outcome data and the equations; pricing the user-requested parlay based at least in part on the alternative probabilities; and causing display of the user-requested parlay by the user computing device.

In some aspects, the techniques described herein relate to a method, wherein the user-requested parlay further includes at least one market recommended to the user.

In some aspects, the techniques described herein relate to a method, wherein the contest is one of a plurality of contests, wherein a common structure of the outcome matrix is shared for each contest of the plurality of contests.

In some aspects, the techniques described herein relate to a method, further including placing pricing limitations on the user-requested parlay based on the alternative probabilities or a potential payout of each of the plurality of user-requested markets or a total payout of the user-requested parlay.

In some aspects, the techniques described herein relate to a method, wherein the user-requested parlay further includes contests from a single sport.

In some aspects, the techniques described herein relate to one or more non-transitory computer-readable media storing computer-executable instructions that, when executed by at least one processor, perform a method of pricing predefined and user-requested markets, the method including: receiving a market request from a user computing device, wherein the market request is for a predefined market; retrieving a query indicative of the predefined market, wherein the query is retrieved from a query lookup table; selecting, by the query, a set of outcome data from an outcome matrix and equations for pricing the predefined market; pricing the predefined market based at least in part on the set of outcome data for pricing the predefined market; and causing display of the predefined market by the user computing device.

In some aspects, the techniques described herein relate to one or more non-transitory computer-readable media, wherein the method further includes: generating the outcome matrix, the outcome matrix searchable by the query.

In some aspects, the techniques described herein relate to one or more non-transitory computer-readable media, wherein the method further includes: receiving a second market request from the user computing device, the second market request for a user-selected market, wherein the market request is a first market request; and generating a second query associated with the user-selected market, wherein the query is a first query.

In some aspects, the techniques described herein relate to one or more non-transitory computer-readable media, wherein generating the second query associated with the user-selected market includes: parsing one or more parameters of the user-selected market; and translating the one or more parameters into a standardized query language.

In some aspects, the techniques described herein relate to one or more non-transitory computer-readable media, wherein the method further includes: receiving, from the user computing device, a cashout request associated with the predefined market; and generating a second query based on the cashout request and the predefined market, wherein the query is a first query and the first query differs from the second query.

In some aspects, the techniques described herein relate to one or more non-transitory computer-readable media, wherein the method further includes: selecting, by the second query, a second set of outcome data from a second outcome matrix for repricing the predefined market; and repricing the predefined market based at least in part on the second set of outcome data for pricing the predefined market, wherein the outcome matrix is a first outcome matrix and the set of outcome data is a first set of outcome data, wherein the first outcome matrix differs from the second outcome matrix.

In some aspects, the techniques described herein relate to one or more non-transitory computer-readable media, wherein one or more events during a contest result in a difference between the first outcome matrix and the second outcome matrix.

In some aspects, the techniques described herein relate to a system for pricing predefined and user-requested markets, the system including: one or more non-transitory computer-readable media storing computer-executable instructions that, when executed by at least one processor, perform a method of pricing the predefined and user-requested markets, the method including: receiving a market request from a user computing device, wherein the market request is for a modification of a leg of a multi-leg parlay; determining if a query representing the modification of the leg of the multi-leg parlay exists in a query lookup table; responsive to the query existing, retrieving the query indicative of the leg of the multi-leg parlay, wherein the query is retrieved from the query lookup table; selecting, by the query, a set of outcome data from an outcome matrix for pricing the leg of the multi-leg parlay; pricing the leg of the multi-leg parlay based at least in part on the outcome matrix for pricing the leg of the multi-leg parlay; and causing display of the leg of the multi-leg parlay by the user computing device.

In some aspects, the techniques described herein relate to a system, wherein the leg of the multi-leg parlay includes a plurality of existing parameters; and wherein the market request for the modification of the leg of the multi-leg parlay is for a parameter modification of an existing parameter from the plurality of existing parameters.

In some aspects, the techniques described herein relate to a system, wherein the method further includes: regenerating the outcome matrix, the outcome matrix regenerated at a predetermined interval.

In some aspects, the techniques described herein relate to a system, wherein the leg of the multi-leg parlay includes a user-requested market.

In some aspects, the techniques described herein relate to a system, wherein the method further includes: regenerating the outcome matrix, the outcome matrix regenerated when an event during a contest occurs.

In some aspects, the techniques described herein relate to a system, wherein the leg of the multi-leg parlay includes a predefined market.

In some aspects, the techniques described herein relate to a system, wherein the method further includes: receiving a second market request from the user computing device, the second market request for a second modification of a second leg of the multi-leg parlay, wherein the market request is a first market request, the modification is a first modification, and the leg is a first leg; and generating a second query associated with the second leg, wherein the query is a first query.

In some aspects, the techniques described herein relate to a method for pricing predefined and user-requested markets, the method including: running a contest simulation including a plurality of simulations of a contest; storing outcome data in an outcome matrix, wherein the outcome data is indicative of probabilities of one or more live events occurring during the contest; receiving a market request associated with a market from a user computing device; selecting, by a query associated with the market request, a set of outcome data from the outcome matrix and equations for pricing the market; pricing the market based at least in part on the set of outcome data for pricing the market; and causing display of the market by the user computing device.

In some aspects, the techniques described herein relate to a method, wherein the market further includes at least one market recommended to a user associated with the user computing device.

In some aspects, the techniques described herein relate to a method, further including: determining whether the market request is for a user-requested market or a predefined market.

In some aspects, the techniques described herein relate to a method, further including: responsive to determining the market request is for the user-requested market, generating the query associated with the market request.

In some aspects, the techniques described herein relate to a method, responsive to determining the market request is for the predefined market, retrieving the query from a query lookup table.

In some aspects, the techniques described herein relate to a method, wherein the query is written in a standardized query language.

This summary is provided to introduce a selection of concepts in a simplified form that are further described below in the detailed description. This summary is not intended to identify key features or essential features of the claimed subject matter, nor is it intended to be used to limit the scope of the claimed subject matter. Other aspects and advantages of the present disclosure will be apparent from the following detailed description of the embodiments and the accompanying drawing figures.

### BRIEF DESCRIPTION OF THE FIGURES

Embodiments of the present disclosure are described in detail below with reference to the attached drawing figures, wherein:

FIG. 1 depicts an exemplary hardware platform relating to some embodiments;

FIG. 2A illustrates an exemplary block diagram relating to a wagering system relating to some embodiments;

FIG. 2B illustrates an exemplary block diagram relating to a simulation engine of the wagering platform relating to some embodiments;

FIG. 2C illustrates an exemplary block diagram relating to a pricing system of the wagering platform relating to some embodiments;

FIG. 3A illustrates an exemplary embodiment of a graphical user interface relating to some embodiments;

FIG. 3B illustrates an exemplary embodiment of a graphical user interface relating to some embodiments;

FIG. 3C illustrates an exemplary embodiment of a graphical user interface relating to some embodiments;

FIG. 3D illustrates an exemplary embodiment of a graphical user interface relating to some embodiments;

FIG. 4A illustrates an exemplary method of generating markets relating to some embodiments;

FIG. 4B illustrates an exemplary method of generating markets relating to some embodiments;

FIG. 4C illustrates an exemplary method of managing risk and liability in user-requested markets relating to some embodiments; and

FIG. 5 illustrates an exemplary method of updating pricing for a user-requested or a predefined market relating to some embodiments.

The drawing figures do not limit the present disclosure to the specific embodiments disclosed and described herein. The drawings are not necessarily to scale, emphasis instead being placed upon clearly illustrating the principles of the present disclosure.

### DETAILED DESCRIPTION

The following detailed description references the accompanying drawings that illustrate specific embodiments in which the present disclosure can be practiced. The embodiments are intended to describe aspects of the present disclosure in sufficient detail to enable those skilled in the art to practice the present disclosure. Other embodiments can be utilized and changes can be made without departing from the scope of the present disclosure. The following detailed description is, therefore, not to be taken in a limiting sense. The scope of the present disclosure is defined only by the appended claims, along with the full scope of equivalents to which such claims are entitled.

In this description, references to “one embodiment,” “an embodiment,” or “embodiments” mean that the feature or features being referred to are included in at least one embodiment of the technology. Separate references to “one embodiment,” “an embodiment,” or “embodiments” in this description do not necessarily refer to the same embodiment and are also not mutually exclusive unless so stated and/or except as will be readily apparent to those skilled in the art from the description. For example, a feature, structure, act, etc. described in one embodiment may also be included in other embodiments but is not necessarily included. Thus, the technology can include a variety of combinations and/or integrations of the embodiments described herein.

Embodiments of the present disclosure are generally directed to systems, methods, and computer-readable media for determining pricing for wagering markets based on a standardized outcome matrix. In some embodiments, data indicative of historical data of contests, users, and current contests is obtained. The data may be used to run a plurality of simulations for a contest with outputs of the simulation being outcome data indicative of events occurring in the contest simulation. In some embodiments, the outcome data may comprise statistical data associated with each contest. From the outcome matrix generated by the plurality of simulations, probabilities of the events and outcomes may be determined. The standardized outcome matrix may be the same across all contests of a same sport and, in some embodiments, across contests of various sports. As such, any wagering markets may be priced by matching stored equations with the data stored in the outcome matrix. The organized data structures and equation mapping provides low latency market pricing without having to run full simulations when new markets are created. As such, markets may be provided to users in real time with low latency without running new simulations to determine new probabilities.

An additional benefit of the outcome matrix generation and the equation mapping is that users may be provided the opportunity to request markets and/or betting opportunities on markets that have not yet been established. Because of the market pricing processes described herein, users may submit requests for markets. The user-requested markets may be provided to a server in a query language and mapped to the outcome matrix data and to the equations to price the user-requested markets. The priced user-requested markets may then be provided to the user by the GUI on the user computing device without running simulations. Predefined markets may be priced through outcome matrix data mapping as well, which may allow for a selection of both predefined markets and user-requested markets to be presented to the user.

In some embodiments, betting markets and any betting opportunity, referenced herein as markets, are provided to the user. A market may relate to a game and comprise a selection for wager. For example, a market may be a team to win, and a selection may be home team or away team. Similarly, or alternatively, the market may be team to win, and the selection may be team A or team B. Another example may be an over/under market where the selection is greater than a specified value (e.g., total point outcome) or less than a specified value. In some embodiments, the user may specify the line or allow a combination that have not yet been determined as described in more detail below. In some embodiments, the markets may be determined based on the user determined markets. As described herein, markets may include selections providing betting lines to user to make wagers on contests (generally, sporting events). In some embodiments, the markets may be predefined, such as by an administrator, sportsbook provider, or any other entity defining betting markets. In some embodiments, markets are a combination of user-requested markets and predefined markets.

In some embodiments, markets, which may be betting opportunities that have not yet been selected as markets, may be generated for contests. Generally described herein, contests will be referenced as sporting events though may extend to any contest such as, for example, a national and/or statewide vote, movie success, movie casting, and any other social event that may be wagered. Contests may relate to complex sports comprising many players comprising a complex variety of outcomes and events such as, for example, basketball, football, baseball, hockey, and the like. In some embodiments, contests may relate to simple sports where a relatively small number of outcomes and wagers may be generated such as, for example racing, NASCAR, horseracing, and the like.

In some embodiments, events may represent anything that may be wagered on in a contest. As such, events may be in-contest occurrences (e.g., field goal in the second quarter, five 3-pointers by a player in the third quarter, 2 interceptions in the first half, and the like) as well as outcome-based events (final score, team with most assists, player assists, player points, and the like). As described herein, an event may be anything that may occur in the game or as an outcome to the events in the game that may be wagered.

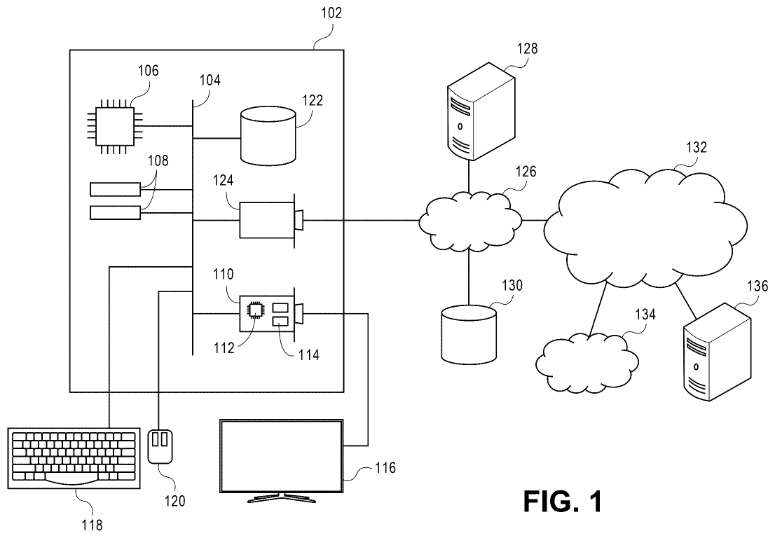

Turning to FIG. 1, an exemplary hardware platform 100 for certain embodiments is depicted. Computer 102 can be a desktop computer, a laptop computer, a server computer, a mobile device such as a smartphone or tablet, or any other form factor of general- or special-purpose computing device. Depicted with computer 102 are several components, for illustrative purposes. In some embodiments, certain components may be arranged differently or absent. Additional components may also be present. Included in computer 102 is system bus 104, whereby other components of computer 102 can communicate with each other. In certain embodiments, there may be multiple buses or components may communicate with each other directly. Connected to system bus 104 is central processing unit (CPU) 106. Also attached to system bus 104 are one or more random-access memory (RAM) modules 108. Also attached to system bus 104 is graphics card 110. In some embodiments, graphics card 110 may not be a physically separate card, but rather may be integrated into the motherboard or the CPU 106. In some embodiments, graphics card 110 has a separate graphics-processing unit (GPU) 112, which can be used for graphics processing or for general purpose computing (GPGPU). Also on graphics card 110 is GPU memory 114. Connected (directly or indirectly) to graphics card 110 is display 116 for user interaction. In some embodiments, no display is present, while in others it is integrated into computer 102. Similarly, peripherals such as keyboard 118 and mouse 120 are connected to system bus 104. Like display 116, these peripherals may be integrated into computer 102 or absent. Also connected to system bus 104 is local storage 122, which may be any form of computer-readable media and may be internally installed in computer 102 or externally and removably attached.

Computer-readable media include both volatile and nonvolatile media, removable and nonremovable media, and contemplate media readable by a database. For example, computer-readable media include (but are not limited to) RAM, ROM, EEPROM, flash memory or other memory technology, CD-ROM, digital versatile discs (DVD), holographic media or other optical disc storage, magnetic cassettes, magnetic tape, magnetic disk storage, and other magnetic storage devices. These technologies can store data temporarily or permanently and may be non-transitory computer-readable media storing data or computer-executable instructions. However, unless explicitly specified otherwise, the term “computer-readable media” should not be construed to include physical, but transitory, forms of signal transmission such as radio broadcasts, electrical signals through a wire, or light pulses through a fiber-optic cable. Examples of stored information include computer-useable instructions, data structures, program modules, and other data representations.

Finally, network interface card (NIC) 124 is also attached to system bus 104 and allows computer 102 to communicate over a network such as local network 126. NIC 124 can be any form of network interface known in the art, such as Ethernet, ATM, fiber, Bluetooth®, or Wi-Fi (i.e., the IEEE 102.11 family of standards). NIC 124 connects computer 102 to local network 126, which may also include one or more other computers, such as computer 128, and network storage, such as data store 130. Generally, a data store such as data store 130 may be any repository from which information can be stored and retrieved as needed. Examples of data stores include relational or object-oriented databases, spreadsheets, file systems, flat files, directory services such as LDAP and Active Directory, or email storage systems. A data store may be accessible via a complex API (such as, for example, Structured Query Language), a simple API providing only read, write, and seek operations, or any level of complexity in between. Some data stores may additionally provide management functions for data sets stored therein such as backup or versioning. Data stores can be local to a single computer such as computer 128, accessible on a local network such as local network 126, or remotely accessible over Internet 132. Local network 126 is in turn connected to Internet 132, which connects many networks such as local network 126, remote network 134 or directly attached computers such as computer 136. In some embodiments, computer 102 can itself be directly connected to Internet 132.

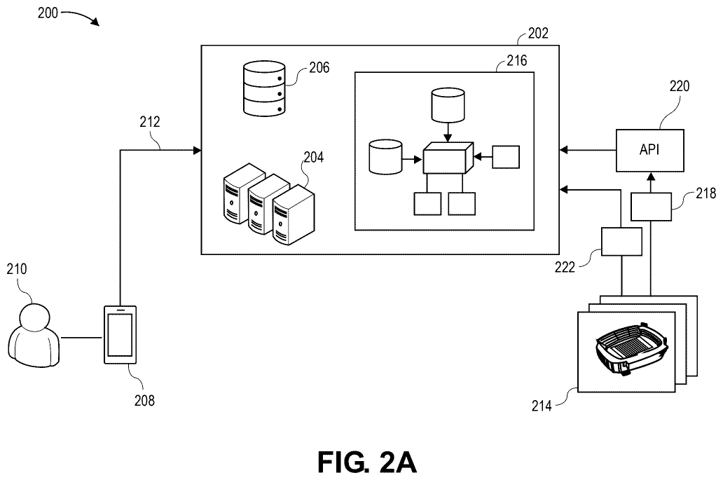

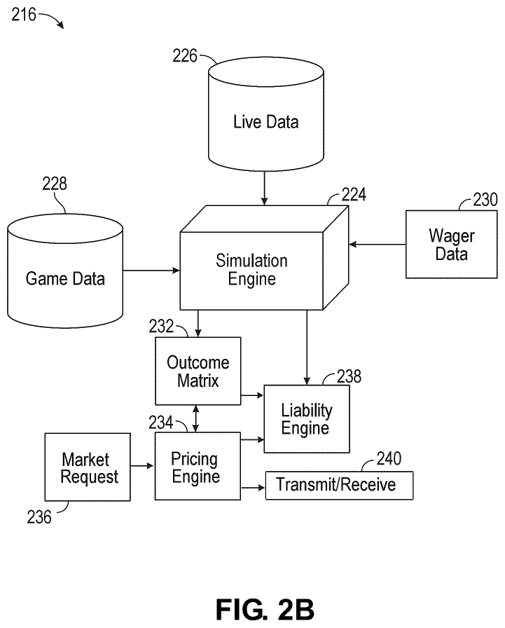

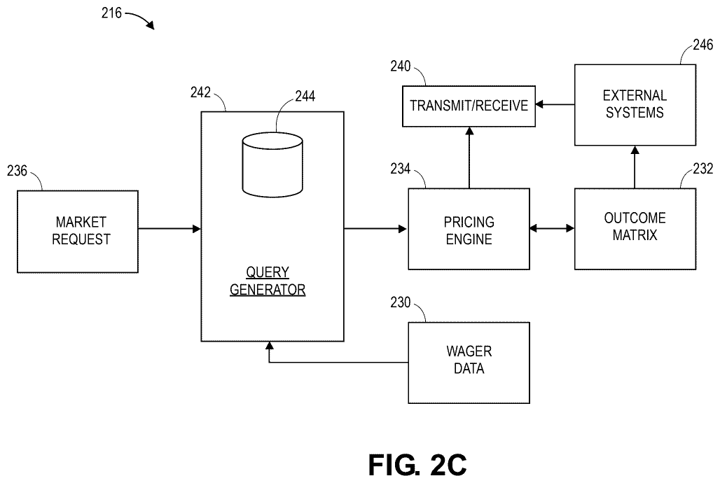

FIG. 2A illustrates an exemplary block diagram 200 of wagering platform or system 202 in accordance with embodiments of the present disclosure. System 202 may include one or more servers such as server 204. In at least one example, the server 204 can include one or more servers or other types of computing devices that can be embodied in any number of ways. For example, the functional components and data of the server can be implemented on a single server, a cluster of servers, a server farm or data center, a cloud-hosted computing service, a cloud-hosted storage service, or the like. Server 204 may be coupled to one or more databases such as databases 206. Databases 206 may store various data for system 202, such as statistical data of past and live contests and user wagering data and user profile data.

The server 204 can communicate with user computing device 208, which may be operated by user 210, via one or more networks such as network 212. The server 204 and the computing device 208 can transmit, receive, and/or store data (e.g., content, information, or the like) using the network 212. The user computing device 208 can be any suitable type of computing device, such as a tablet computing device, a smart phone, a laptop, a desktop computing device, or any other computing device discussed above with respect to FIG. 1. While a single user computing device 208 is illustrated, any number of computing devices operated by any number of users may communicate with system 202. The computing device 208 can, among other functions, be operable by user 210 to interface with system 202 to place wagers on contests in accordance with embodiments of the present disclosure. For example, computing device 208 may execute an application for interfacing with server 204 to place wagers on contests.

Network 212 can include, but is not limited to, any type of network known in the art, such as a local area network or a wide area network, the Internet, a wireless network, a cellular network, a local wireless network, Wi-Fi and/or close range wireless communications, Bluetooth®, Bluetooth Low Energy (BLE), Near Field Communication (NFC), a wired network, or any other such communication network, or any combination thereof as describe above in reference to FIG. 1.

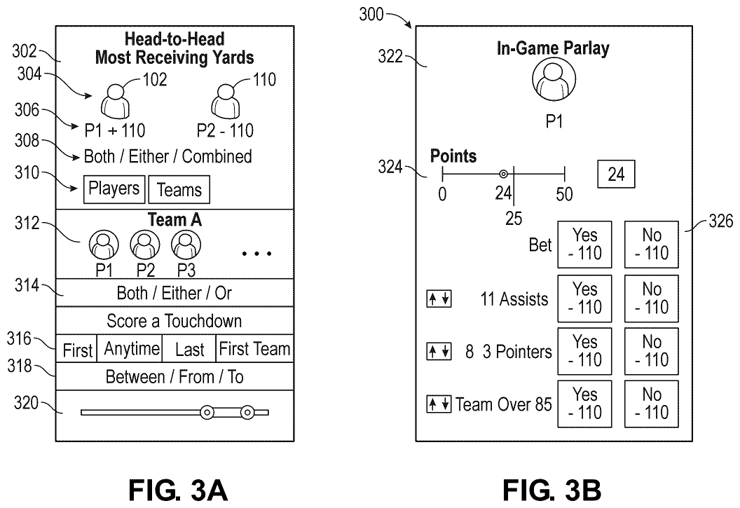

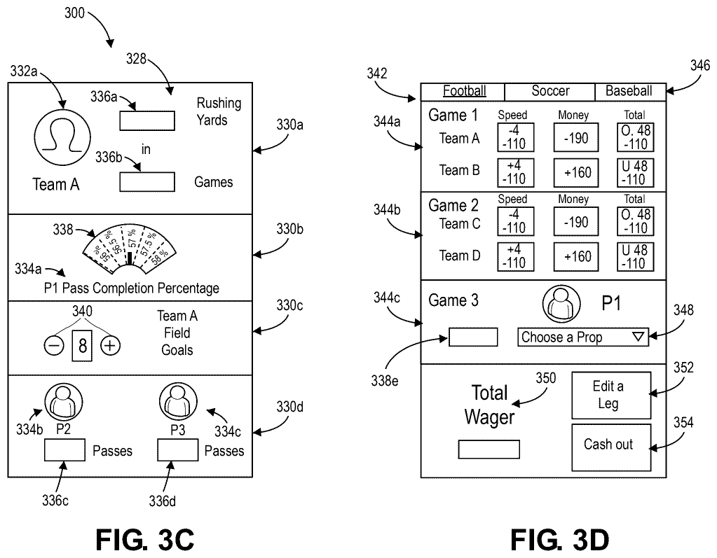

As discussed, user 210 may place wagers on future and/or live contests 214, which may be events, such as sporting events, eSports, or the like. In some embodiments, system 202 may cause display of a graphical user interface (GUI 300, FIGS. 3A-3D) for interaction by user 210. GUI 300 may provide an interface for user 210 to place bets and request markets by computing device 208 as described herein.

User 210 may interact with GUI 300 to receive markets and place bets before and/or during live contest 214. During live contest 214, server 204 may be configured to receive market requests from computing device 208 and run calculations to generate the requested markets based on the probabilities identified in outcome matrix 232 (FIG. 2B). These calculations and updates to the markets and pricing may be performed automatically as described below or the betting parameters may be changed manually by any authorized administrator. In some embodiments, the markets may be individual betting lines or may be combinations of markets referenced herein as parlays. Simulations, markets, parlays, and user-requested markets are discussed in more detail below.

In some embodiments, system 202 comprises pricing system 216. Pricing system 216, in some embodiments, comprises or has access to various databases, processors, computer-readable media storing computer-executable instructions, and the like. Pricing system 216 may comprise computing hardware platform 100. Pricing system 216 may be configured to receive any data associated with events (e.g., live contest 214), previous events, player and team statistics, and the like. Furthermore, pricing system 216 may store or otherwise have access to user profile data associated with user 210. The user profile data may include any information that may be useful in providing user 210 with customized wagering data including, favorite teams, favorite players, favorite betting practices, and the like. As such, user 210 may be specifically targeted for markets and parlays.

In some embodiments, pricing system 216 may be configured to run simulations of events based on the input data described above. The output of the simulation may be outcome matrix 232, which may be standard across various contests and sports. In some embodiments, outcome matrix 232 may provide a standard set of data that may be used for calculating markets and parlays to provide to user 210. As such, any contest (e.g., basketball game, football game, baseball game, soccer game, Olympics, NASCAR, and the like) including players, time and period, and the like, may be output and stored in outcome matrix 232 for determining probabilities of events for pricing markets and parlays for user 210. The simulations and outcome matrix 232 are described in more detail below.

In some embodiments, system 202 is coupled to various data sources for receiving data from the data sources for processing by pricing system 216. The data may be stored data (e.g., in database 206), data received in real time, or both. In some embodiments, the data includes play-by-play data 218 from live contest 214, which may be received via an API 220 in some embodiments. System 202 may be subscribed to in a publisher-subscriber (PubSub) architecture. For example, the API 220 may publish messages containing play-by-play data 218 substantially in real-time (e.g., about every two seconds). Broadcast data 222 may also be communicated to system 202 for use by pricing system 216. Generally, other data sources may include social media data, media data, which may be obtained prior to the live contest beginning (e.g., articles, podcasts, television shows, etc.), and the like. In some embodiments, data leveraged to determine a narrative, generate markets, map wagers, and the like may include data stored in database 206, which may include statistical data for players and teams participating in the live contest 214, historical wager data relating to user 210 and/or to multiple users, past contests, past wagers, and the like.

FIG. 2B depicts an embodiment of pricing system 216. As shown, pricing system comprises simulation engine 224, live data 226, historical data 228, wager data 230, as well as output of simulation engine 224 outcome matrix 232 and pricing engine 234 and liability engine 238. Historical data 228 comprises data from past contests and may come from a plurality of databases. In some embodiments, historical data 228 comprises data from past events such as, for example, previous games, races, matches, and the like. The past events may include any sport, contest, vote, and the like. Historical data 228 may include any data associated with the event such as, for example, game statistics, team statistics, player statistics, weather conditions, crowd numbers, date, time, and the like. For example, historical data for a football game may include rainy weather, average wind conditions, Monday night game, team A versus team B, duration of each quarter, duration of each drive, team with the ball first, second, last, injuries, first play run or pass, first play after half time run or pass, number of runs, number of passes, completion percentage, receptions, turnovers, and the like. All data associated with any contest may be included in historical data 228 such that historical data 228 may be used to run simulations on future games and determine probabilities associated with future contests to the highest degree of accuracy available. Though football is discussed in examples herein, historical data 228 may include any sport, contest, match, or any other event that may be wagered.

In some embodiments, live data 226 comprises data indicative of a contest that is currently underway (e.g., live contests 214). Live data 226 may update periodically, such as when a football play is run, when a boxing round has finished, when a tennis point is scored, and the like. In some embodiments, live data 226 may continuously update as quickly as possible to keep up with continuing action such as, for example, when the contest is a soccer game, a basketball game, and the like. Live data 226 may be used to calculate in-game markets to present to user 210. In-game markets may comprise, for example, next player to score, first player to score in the second half, first play of the next quarter, what will the next play be, and the like. Any in-game statistical data may be wagered for in-game betting, and any in-game market may be generated in real time utilizing outcome matrix 232. Furthermore, in-game user-requests markets may also be received and generated in near real time during events as described in embodiments below.

In some embodiments, wager data 230 comprises historic and current wagers associated with events and users. Wager data 230 may comprise any data associated with user-requested markets and previous wagers. Furthermore, wager data 230 may comprise any data that is submitted by user 210 for requesting markets and making wagers. As such, any wager data may be included in any simulation and may be used by liability engine 238 for determining risk and liability.

In some embodiments, simulation engine 224 comprises algorithms for running simulations on future contests. Any machine learning algorithm such as, for example, neural networks, linear regression, deep learning, random forest, decision-making algorithms may be used. As discussed herein, Monte Carlo simulations may be used. For example, a contest simulation may comprise 5,000, 10,000, 20,000, or more individual simulations of the contest set by the above-described data inputs modeled with randomness provided to generate variability in the simulations. Furthermore, the data inputs may also comprise the events within the simulations and the events may further be the output of the simulation. In some embodiments, the output data may comprise 100-300 events, which may be statistical data for each player and team over ranges of the contest as well as overall outcomes (e.g., total points, win/loss, and the like). In this example, the 20,000 simulations providing 20,000 rows of event data may result in a significant total data to calculate probabilities of the events occurring over the course of the contest.

In some embodiments, the outcome data may be stored in outcome matrix 232. Outcome matrix 232 may comprise all outcome data associated with each event that may occur over the course of the simulated contest. As such, outcome matrix 232 may be queried, selecting stored outcome data from fields of outcome matrix 232 to input into stored equations to calculate probabilities of the events occurring. As such, outcome matrix 232 may store all data necessary for pricing given markets.

In some embodiments, pricing engine 234 may receive market requests from market requests 236. In some embodiments, market requests 236 comprises queued markets. The queued markets may be standard markets such as point totals, over/under, team win/lose, and the like, which may be calculated upon completion of the contest simulations. In some embodiments, market requests 236 may comprise user-requested markets. Market requests 236 may be priced before receiving at pricing engine 234 as in standard markets or priced at pricing engine 234 based on the previously stored matrix if the market request is a user requested market. In some embodiments, the data from market requests 236, before or after pricing, may be formatted as a query language compatible with outcome matrix 232 such that data from data fields, rows, and columns, may be added based on the market requests 236. Therefore, any data may be added to the outcome matrix 232 from standard markets and user requested markets and priced at pricing engine 234 utilizing the updated matrix and/or the previously stored matrix.

In some embodiments, pricing engine 234 may determine probabilities based on the query (based on the market requests 236) and the outcome data extracted. For example, as described in embodiments below, the query may define data to be extracted along with equations to use to calculate the probabilities and the lines associated with the market requests 236. The equations may be extracted from an equations table stored, for example, at datastore 206, and the extracted data may be input into the equations to calculate probabilities and betting lines to be associated with the requested markets. As such, any requested market may be priced by querying the pricing engine 234, which in turn calculates the probabilities and price using the data stored in the outcome matrix 232.

Furthermore, in some embodiments, liability engine may calculate risk and liability. Outcome matrix 232 may comprise any data for calculating probabilities for events to occur during the course of the simulated contest. Furthermore, pricing engine 234 may calculate betting lines associated with the markets provided to user 210. Furthermore, wager data may include all data wagered by the user, which in some embodiments, may be provided directly to pricing engine 234 as pricing engine 234 output may be provided to the user and wager data may be received from user 210 by communication system 240. As such, liability and risk may be determined and managed at liability engine 238 as described in embodiments below.

FIG. 2C illustrates an exemplary pricing system in accordance with embodiments of the present disclosure and generally referred to by reference numeral 216. Broadly, it may be desirable for systems to allow users to both request markets as well as select from predefined markets (such as queued markets discussed above), as doing so may result in greater flexibility relative to systems only providing predefined markets. Additionally, systems providing both user-requested markets and predefined markets may cater to a larger audience, as users who prefer to wager on predefined markets and users who prefer to define their own markets may utilize a single platform. Accordingly, pricing system 216 may be integrated into systems (such as system 202) providing predefined markets and/or user-requested markets to users. For example, pricing system 216 may be integrated into an existing sports betting system, where a user is presented with a set of predefined markets for placing wagers. A predefined market may be a static market predefined by a system, person, or entity (such as a sportsbook provider) where the selections associated with the wager are preset prior to offering the market to a user. For example, a set of predefined markets may include a listing of moneyline wagers for all NFL teams playing during week 2 of the NFL season.

Market request 236 may include a request for one or more user-requested markets, predefined markets, or a combination of user-requested and predefined markets. At a high level, as described above, pricing engine 234 may be queried with market request 236. As such, market request 236 may be put in the format of a query such that the parameters of market request 236 are mappable to outcome matrix 232. In some embodiments, prior to querying pricing engine 234, query generator 242 determines a query representing market request 236. The queries provided by query generator 242 may be in a standardized format understandable by pricing engine 234.

Market request 236 may include a request for one or more user-requested markets, predefined markets, or a combination of user-requested and predefined markets. At a high level, as described above, pricing engine 234 may be queried with market request 236. As such, market request 236 may be put in the format of a query such that the parameters of market request 236 are mappable to outcome matrix 232. In some embodiments, prior to querying pricing engine 234, query generator 242 determines a query representing market request 236. The queries provided by query generator 242 may be in a standardized format understandable by pricing engine 234.

In some embodiments, query generator 242 may traverse query table 244 to determine a query representing market request 236. Query table 244 may include one or more predefined queries associated with one or more markets. Accordingly, instead of generating a new query for a predefined market, query generator 242 may retrieve an existing query associated with the predefined market from query table 244.

In some embodiments, as discussed above, wager data 230 may include a plurality of predefined markets. Accordingly, query generator 242 may receive the plurality of predefined markets from wager data 230, generate queries associated with the plurality of predefined markets received from wager data 230, and store the generated queries in query table 244. In other embodiments, wager data 230 may include a plurality of queries associated with predefined markets. Accordingly, query generator 242 may store the plurality of queries in query table 244. In still other embodiments, query generator 242 may receive a plurality of unstandardized queries associated with predefined markets from wager data 230, translate the unstandardized queries into a standardized language, such as PQL, and store the standardized queries in query table 244.

Query table 244 may be any data store type now known or later developed, including, but not limited to, a relational database, a NoSQL database, a key-value store, a document store, a graph database, an in-memory data grid, a flat file, a cloud storage solution, a message queue, or any similar data store type. In some embodiments, query table 244 is a singular data store. In other embodiments, query table 244 is a plurality of data stores. In some embodiments, query table 244 is a cloud-based data store.

It is contemplated herein that a user-requested market may be requested a plurality of times by a plurality of users. For example, during a basketball game, multiple users may request the same market regarding the final score of the game. Thus, it may be advantageous to store queries associated with a user-requested market that has been requested multiple times over a predetermined period of time, rather than regenerating the query associated with the user-requested market. In some embodiments, queries may be stored in query table 244 for user-requested markets. For example, if a particular user-requested market is requested by a plurality of users, query generator 242 may store a query associated with the user-requested market in query table 244. Thus, if the user-requested market is requested again, query generator 242 may write the query associated with the user-requested market to query table 244 for storage. Accordingly, query generator 242 may retain a history of user-requested markets in which queries have been generated. For example, query generator 242 may retain a history of the last 30,000 user-requested markets to determine if a newly received market request 236 has been requested within the last 30,000 market requests. If query generator 242 determines market request 236 has been requested 200 times, for example, query generator 242 may generate the query associated with market request 236 and write the query to query table 244. Thus, if an additional market request is received for said market, query generator 242 may read from query table 244, thus saving the time and computation resources it would have taken to generate a new query.

In some embodiments, query generator 242 may generate a query associated with a user-requested market from market request 236. Query generator 242 may parse market request 236 to determine the parameters defining the market. For example, if a market request is for “team A having 177 rushing yards by the end of Game X,” parameters may include team A, game X, rushing yards, end of the game, and the value 177. Accordingly, query generator 242 may generate a query including the parameters needed by pricing engine 234 to determine the price associated with market request 236. As stated above, the queries generated by query generator 242 may be in a standardized format. This is advantageous, as pricing engine 234 and outcome matrix 232 may be optimized for running queries in a standardized format, thus resulting in greater time efficiency.

After generating a query, query generator 242 may transmit the query to pricing engine 234. Accordingly, pricing engine 234 may determine a price associated with the query (and, consequently, market request 236). As described above, pricing engine 234 may determine probabilities based on the query received from query generator 242 as well as outcome data stored in outcome matrix 232. As further described above, outcome matrix 232 may include all outcome data associated with each event that may occur over the course of the simulated contest. Outcome matrix 232 may contain fields associated with parameters of a query, including sport, team, player, value, proposition, outcome type, time of occurrence, and other parameters. As such, outcome matrix 232 may be queried by pricing engine 234, where stored outcome data from fields of outcome matrix 232 are retrieved to input into stored equations to calculate probabilities of the events occurring. After determining the probabilities, pricing engine 234 may calculate a price associated with market requests 236.

After determining the price associated with market request 236, pricing engine 234 may transmit the price to the user through communication system 240. For example, the price associated with market request 236 may be auto populated on a UI presented to the user on the client device associated with the user. Accordingly, the user may know the price of placing a wager, updating a wager, or cashing out on a wager for a specific market before doing so (as discussed further below).

In some embodiments, alternatively or in addition to generating queries for predefined markets, outcome matrix 232 may include a matrix specifically generated by simulation engine 224 for the predefined markets. For example, wager data 230 may provide simulation engine 224 with the one or more predefined markets. Accordingly, simulation engine 224 may generate outcome matrix 232 exclusively for pricing the one or more predefined markets. In some embodiments, outcome matrix 232 includes separate matrices for the predefined markets and for the user-requested markets. In other embodiments, a portion of outcome matrix 232 is dedicated to the one or more predefined markets.

In some embodiments, the portion of outcome matrix 232 associated with the predefined markets is transmitted to external systems 246, where external systems 246 may determine the prices associated with the predefined markets. For example, if pricing system 216 is integrated into a legacy system with traditional pricing techniques, outcome matrix 232 may be transmitted to the subsystems of the legacy system performing traditional pricing techniques. Accordingly, external systems 246 may transmit the pricing information for market request 236 to a user through communication system 240.

FIGS. 3A-3D depict an exemplary GUI 300 for user 210 to interact with system 202 as described above. In some embodiments, GUI 300 provides markets for user 210 to select to make wagers. Furthermore, GUI 300 may receive user market requests. As depicted in FIG. 3A, GUI 300 may comprise pre-game screen 302 providing exemplary head-to-head markets. For example, continuing with the exemplary football contests described above, exemplary market 304 may be receiving yards, and the selection 306 may be player 1 (P1) to equal/exceed/not exceed 102 yards or player 2 (P2) to equal/exceed/not exceed 110 yards or both players to equal/exceed/not exceed the given value at head-to-head selection 308. Furthermore, a betting line is provided as calculated by pricing engine 234 described above. The markets, selections, and parlays described herein may be determined from outcome matrix 232, comprising the simulation data for each contest, including player, team, and the like, as described above. Here, user 210 may select various teams and players at team/player selection 310 and select players at player selection 312 as well as both/either/or selection 314 to score at a time frame 316 such as touchdown first/anytime/last/first team or the like. These markets for selection by the user may be provided by pricing system 216.

Furthermore, in some embodiments GUI 300 may provide ranges 318 by range slider 320. Here, user 210 may select ranges for points, receptions, assists, blocks, kicks, goals, wins, and the like. User 210 may customize any of the markets and submit the customized markets as a user-requested market. For example, user 210 may select receiving yards for P1 and change from 102 to 115 and submit the user-requested market to server 204. The user-requested market may automatically be input as the above-described query language to server 204. Server 204 may then obtain the data from outcome matrix 232 corresponding to the query and perform a corresponding calculation (retrieved from the calculations table) to calculate the new market (e.g., user-requested market) requested by user 210. The new market may then be transmitted back to user computing device 208 and displayed to user 210 by GUI 300. For example, the new market may be {p1, receiving yards, 115, −200}. In another example, user 210 may operate range slider 320 to select a range of possible outcomes. For example, user 210 may select P2 to score a field goal sometime between the two-minute warning and halftime of a football game. The user-requested market may be provided to server 204 and a probability calculated based on the stored calculation data and outcome matrix 232. The user-requested market may be returned {P2, field goal, made, Q2, <2:00, −150}. The market syntax provided here is exemplary only and any syntax/language may be used. The market may be provided to the user in a matter of milliseconds, as described above, as a full simulation is not required. The full simulation is not required due to the storage of the standardized outcome matrix 232 along with the calculation table and the query language mapping the calculation to the corresponding data in outcome matrix 232. As such, pricing engine 234 may calculate probabilities of events associated with user-requested market occurring from the outcome data of outcome matrix 232.

Any user-requested market may be calculated at server 204 using outcome matrix 232 to make the calculation at pricing engine 234. Server 204 may be directed by a query language specifically designed to locate the necessary fields in outcome matrix 232 to perform the calculation to provide the user-requested market. As such, a new simulation does not need to be run and the user-requested market can be provided to the user in near real time (e.g., typically around 100-500 milliseconds for end-to-end time). In some embodiments, the query language may be Probability Query Language (PQL); however, any suitable query language, outcome matrix data structure, and calculations table, may be used.

It should be noted that any markets described herein may be provided in combination as parlays. User 210 may request any markets in combination as user-requested parlays. Each market request may be evaluated in combination calculating probabilities for each requested outcome, combinations of requested outcomes, as well as the total probability for all outcomes for the requested markets. in determining pricing for each market, each combination of probabilities, and/or the total parlay, may be determined by mapping the data fields associated with the requests from the outcome matrix 232 to the associated stored calculations in pricing engine 234. As such, the time to provide parlays to computing device 208 is performed in near real time as described above.

FIG. 3B depicts an exemplary in-game screen 322 of GUI 300 providing in-game parlays (e.g., a combination of markets). In some embodiments, in-game markets and in-game parlays may be generated by system 202 and provided to user 210 by GUI 300. In an exemplary scenario here, slider 324 is provided for user 210 to input a market requesting a specific points total and/or over/under total. The points total provided initially by GUI 300 is 25; however, user 210 has input 24 as the point total and may input any total that is allowable based on the liability discussion below. Therefore, the user-requested market is for a total of 24 points by P1. Furthermore, additional markets 326 are provided including assists, 3 pointers, and team over/under. Each of the markets may be wagered independently and/or any combination may be wagered together as a parlay. Furthermore, each of the markets may be provided to user 210 based on the user profile including a history of the user wagers and user preferences (e.g., wager types, favorites, and the like). In some embodiments, each of the markets may be modified to or provided by user 210 as user requests. When the user-requested markets are submitted, as described above, the user request may be generated in a specific query language and transmitted to server 204. At server 204, the query may be mapped to stored calculations from the calculations table and data fields in outcome matrix 232.

In some embodiments, as shown by slider 324, market requests may be limited. The limitations to each market, in some embodiments, may be based at least in part on the probability of associated outcomes. For example, as shown in FIG. 3B, P1 points total is limited to 50 points. The limit may be based on a probability to score more than 50 points and the associated probability is therefore associated with the market pricing. For example, the probability that P1 will score 50 points may be determined by the above-described simulations to be in 1%, 5%, 10%, 20%, or the like of simulated games. As such, the limitation may be decided based on the probability for the player to score 50 points according to the simulations. Any threshold value may be provided on either end of the range. For example, it also may be equally unlikely that P1 scores less than 6 points. As such, the same limitation may be applied.

In some embodiments, the limitations applied above may be set based on market pricing and the potential for large losses to control risk and liability by system 202. For example, as the probability reduces for a specific, or combination, of outcomes, the payout may also increase. Continuing with the exemplary football game above, an over/under market may be provided by system 202 for game A in which an over/under total of 45 points is provided with an over selection of −115 and an under selection of −110. User 210 may request a new market where the over/under for the game is 30. After analysis at server 204, the user-requested market may be returned with an over selection of +150 and an under selection of −140. Similarly, or alternatively, user 210 may provide a request for a market with an under/over total of 10 points. This outcome may be determined to occur in 2% of simulations providing a market of 10 points with an over of +1200 and an under selection of −1150. This payout may be outside of the set limitations of wagers based on liability restrictions. As such, the market may not be provided to the user 210 and a limitation on the lowest point total allowable may be provided to the user as, for example, 16.

Furthermore, in some embodiments, similar limitations may be set on parlays to control risk and liability. Scenarios may occur in which each individual market may be acceptable, but the combination of markets requested for a parlay may lay outside of the limitations provided for risk. For example, a 1000-to-1 payout may be the limitation. This payout may come with very unlikely probability of payout, but it may be determined that it is too much to risk. As such, any parlay that exceeds this potential payout may be prevented. In some embodiments, alternative parlays that fall within the provided limitations may be recommended to the user based on the user-requested parlay and comprising one or more of the user-requested markets.

FIG. 3C depicts an exemplary screen 328 of GUI 300 for providing markets to users using a variety of UI elements, in accordance with embodiments of the present disclosure. Broadly, GUI 300 may provide UI elements capable of providing a user with the ability to tailor user-requested market selections. For example, GUI 300 may provide UI elements such as sliders, dials, drop-down menus, plus and minus buttons, toggle switches, radio buttons, numeric input fields, stepper controls, scrollbars, draggable handles, spin boxes, range selectors, and other UI elements. UI elements allowing for the selection of a value may provide a user the ability to specify a value for a selection, thereby tailoring the market to their desired parameters.

Markets and selections for those markets may be tailorable on multiple levels, such as the proposition being bet on, the value of a proposition, and the person, place, entity, team, etc., the bet is directed towards. In some embodiments, a market is tailorable with respect to the person, sport, and/or team a market is directed towards. For example, bet line 330a may be on team 332a, where team 332a is “Team A.” For another example, bet line 330b may be on player 334a (P1), and bet line 330d may be on player 334b (P2) and player 334c (P3).

In some embodiments, a market is tailorable with regard to the proposition being wagered on. For example, bet line 330a may be regarding the number of rushing yards over a specified number of games, such as 250 rushing yards over 2 games. For another example, bet line 330b may be regarding the pass completion percentage of a player for a game. For still another example, bet line 330c may be regarding the number of field goals for a team during a game, while bet line 330d may be with regard to the respective number of passes of two players during a game.

A variety of UI elements may be used to receive input regarding the selections for the value of propositions. For example, plus-minus button 340 may increase or decrease the amount specified by plus or minus one, while dial 338 may increase the amount specified by plus or minus a half. In some embodiments, the value of a proposition may be input through an input box, such as input box 336a for rushing yards, input box 336b for game numbers, input box 336c for passes, and input box 336d for passes. Input boxes may allow a user to specify a value for a proposition using any number of digits. For example, a user may be able to input the value “212.3” into input box 336a and the value “2” into input box 336b such that bet line 330a is for “Team A to have an average of more than 212.3 rushing yards in the playoffs.”

FIG. 3D depicts an exemplary screen 342 of GUI 300 for providing multi-leg parlays with both predefined markets and user-requested markets. GUI 300 may allow a user to create multi-leg parlays with user-requested markets, predefined markets, or a combination of user-requested markets and predefined markets. As discussed above with respect to FIG. 2C, queries may be generated for the bet lines of the multi-leg parlay, allowing the multi-leg parlay to be priced using the outcome matrix. By utilizing an outcome matrix, multi-leg parlays that combine user-requested markets with predefined markets may be specified by a user. Such multi-leg parlays may be created for any number of events, including, but not limited to, sporting events, soccer matches, football games, basketball games, baseball games, swimming events, horse races, and any other sport. For example, bar 346 lists three sports available for wagering: football, baseball, and soccer. Additionally, bar 346 highlights the sport currently selected for wagering—that is, football. It is contemplated herein that the legs of a multi-leg parlay need not be confined to a single sport; instead, a multi-leg parlay may combine legs from multiple sports.

To illustrate, exemplary screen 342 may be a multi-leg parlay with three legs. Leg 344a and leg 344b may be predefined markets, such as money lines specified by a sportsbook platform. Leg 344c, however, may be a user-requested market. Leg 344c may allow a user to determine a proposition to bet on using drop-down menu 348. Additionally, leg 344c may include an input box 338e, where the user may specify a value to wager on for a selected proposition. For example, a user may select the proposition of field goal percentage for P1 for a game and specify a value of 100%. As such, user-requested market may be for P1 to have a 100% field goal percentage during a specific game. Upon the price being determined by referencing the outcome matrix, the total price for the multi-leg parlay may be displayed in total wager box 350.

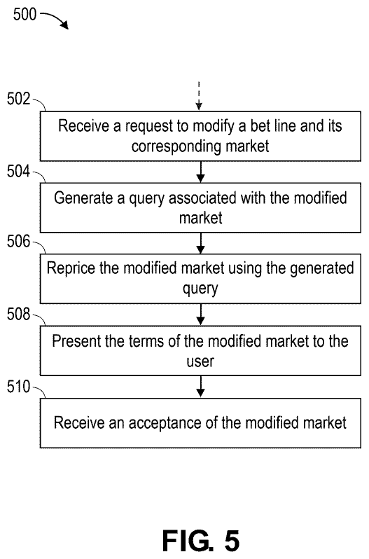

In some embodiments, as discussed below with regard to method 500, a wager may be modified, including, but not limited to, one or more legs of a multi-leg parlay. As such, exemplary screen 342 may include “edit a leg” button 352 and/or “cash out” button 354. If “edit a leg” button 352 is actuated, a user may specify one or more legs of the multi-leg parlay to modify and which parameters of the leg to modify. Similarly, if “cash out” button 354 is actuated by a user, the user may specify one or more legs of the multi-leg parlay to cash out. Accordingly, as discussed below with regard to FIG. 5, a query may be generated for the modified leg, and the query may be used to price the modified leg.

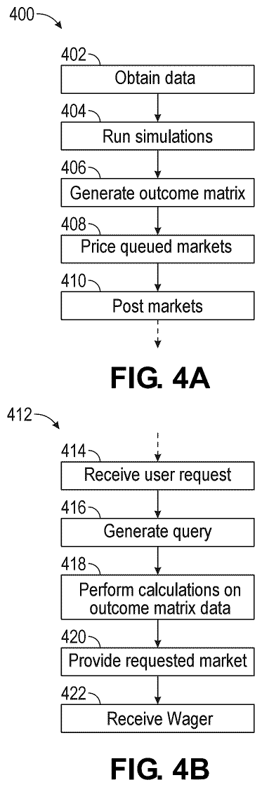

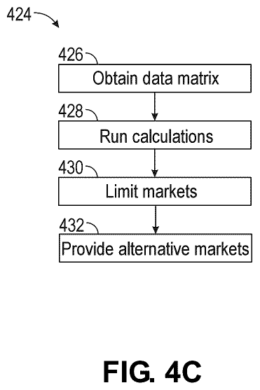

FIG. 4A depicts an exemplary flow chart 400 illustrating a method of providing markets to users by system 202. At step 402, system 202 obtains data from databases comprising previous contest data, user profiles, current in-progress contests, and the like as described in embodiments above. The data may be stored on a local datastore and/or stored remotely and accessible by system 202. The data may be obtained and stored locally while being used to generate outcome matrix 232 and probabilities for contests as described below.

At step 404, system 202 runs one or more contest simulations comprising a plurality of simulations of the one or more contests. The plurality of simulations may simulate the one or more contests a plurality of times comprising historical statistics providing known parameters associated with teams, players, and the like, and variability included as random error to generate variability in the simulated contests. In some embodiments, the contest simulation may be a Monte Carlo algorithm that runs approximately 20,000 simulations for each contest. The output of the simulation may be data indicative of events that user 210 may wager on for the contest. For example, the outputs may be team statistics, player statistics, in-contest events, and the like, as described in embodiments above.

At step 406, system 202 generates outcome matrix 232 comprising outcome data and probabilities of the outcome data from the simulation of step 404. In some embodiments, outcome matrix 232 comprises player and team statistics as well as outcome data from the simulations such as, for example, winning team, final scores, probabilities for players and teams, and calculated probabilities for events to occur during the contests based on the simulations. In some embodiments, outcome matrix 232 includes the outcomes directly from all simulations. For example, outcome matrix may include 20,000 rows/columns for each simulation and various corresponding columns/rows including the event occurrences for each simulation. As such, data from each field, row, and/or column may be extracted for calculation of probabilities. For example, in a simulated college basketball game the underdog won 43% of the games across 20,000 simulations. The favorite team odds can easily be calculated by pricing engine 234, and a corresponding market can be provided to user 210 as described above.

At step 408, system 202 prices queued markets from market requests 236 using outcome matrix 232 and equations from the calculations table. In some embodiments, a known set of markets may be set for corresponding contests. The known set of markets may be based on popularity as well as traditional betting markets and the like.

In some embodiments, the known set of markets may be customized, or filtered, based on user preferences, a history of user wagers, and the like. For example, a user profile may indicate that user 210 prefers to wager on total points and over/under. As such, total points and over/under may be provided to user computing device 208 as well as any other markets that may be determined as having a high probability of user 210 wagering based on user history and similar users.

At step 410, system 202 causes display of the priced markets by GUI 300 on user computing device 208. The priced markets may be provided by server 204 to user 210 by user computing device 208. The markets may be provided before the start of the contest or during the contest. Furthermore, the markets may be provided as a single wagering opportunity or markets may be combined in a parlay as described above.

FIG. 4B depicts an exemplary flow chart 412 illustrating a method of generating a market based on user-requested markets from user 210. In some embodiments, FIG. 4B may be an extension of the method illustrated in FIG. 4A. For example, FIG. 4A depicts an exemplary embodiment, of providing standard markets by the standardized outcome matrix 232. Further, generating outcome matrix 232 provides opportunities for user 210 to customize and request markets that may be priced in real time without further simulations. As such, with the already generated outcome matrix 232, the method may continue with user 210 providing user-requested markets.

At step 414, system 202 may receive the user-requested market from GUI 300. The user-requested market may be a single market with parameters provided by user 210 or may be a combination of markets provided individual or in combination (e.g., a parlay). User 210 may interact with GUI 300 to combine pre-existing markets provided in step 410 above, and/or may alter markets, and/or may create new markets for submitting as user-requested markets.

At step 416, the user-requested market may be received in a specific query format for querying outcome matrix 232 and mapping equations to outcome data. For example, outcome matrix 232 may comprise the simulation data from the above-described approximately 20,000 simulations, or more, and/or any calculated probabilities and statistics associated with the combined simulations.

At step 418, the query may also cause selection of equations from a calculations table for calculating probabilities from the selected outcome data and, from the calculated probabilities, determine betting lines for the user-requested market by pricing engine 234. As such, any market may be generated from the user-requested markets if the requested data exists in the simulations and a calculation is stored to generate the probabilities of any user-requested event occurring during any contest. Furthermore, the user-requested market may be priced completely from the outcome data of outcome matrix 232 by pricing engine 234 without running a new simulation.

At step 420, the priced user-requested market is provided to user computing device 208 by server 204 and displayed by GUI 300. The techniques described herein generate the priced user-requested market in a time frame of approximately 200-500 milliseconds. As such, the user-requested market may be provided to user 210 in near real time. User 210 may then decide if they want to select and submit a wager for priced user-requested market at step 422.

FIG. 4C depicts an exemplary flow chart 424 illustrating a method of risk and liability control. The steps illustrated here may be provided independently of FIGS. 4A and 4B; however, in some embodiments, the steps of FIG. 4C may be provided with the methods illustrated in FIGS. 4A and 4B. For example, the risk and liability control may be performed between steps 408 and 410 of FIG. 4A and/or between steps 418 and 420 of FIG. 4B. As such, any risk and liability analysis may take place before the markets are provided to user 210. As described above, in some embodiments, the risk and liability analysis may be performed independently to provide the markets to user 210 as quickly as possible. In some embodiments, steps 426-432 may be performed after outcome matrix is generated and/or after probabilities and pricing has been calculated.

At step 426, priced market data and/or simulation data may be obtained by liability engine 238. In some embodiments, liability engine 238 may use outcome matrix 232 and/or may use simulation engine 224 output to generate a liability outcome matrix. Either way, risk may be determined based on the simulation data and the markets as described in embodiments above.

At step 428, calculations may be performed on the market data and the simulation data to determine a level of liability of the company responsible for payout and providing the market. The calculations may determine the probability of events occurring in the contests and the payout based on the priced markets. Here, the priced markets may either be standard markets provided by system 202 or user-requested markets. The payout and/or probabilities may be compared to threshold values. If the payouts/probabilities are above or below the threshold values, in some embodiments, the markets may be limited.

At step 430, markets may be limited and/or blocked by liability engine 238. If the payout/probability for a particular market or combined markets is above (or below) a threshold value, the market may be limited or blocked. For example, a wager amount may be limited if the probability of an event occurring in a contest is below 0.02, 0.05, 0.10 or any other value. This may limit the potential payout if the event occurs. Furthermore, in some embodiments, wagers may be limited and/or blocked in payouts that are calculated to be greater than a specific amount.

In some embodiments, there may be high randomness associated with some markets. The high randomness and/or outliers in events may present high risk to the company and may be limited by limiting/blocking wagers as well as modifying (e.g., increasing) the price of wagers. Therefore, randomness and error bars may be tracked and, if greater than a threshold amount, wagers may be limited, markets may be blocked, and/or wager prices may be modified.

At step 432, alternative markets may be provided. In some embodiments, when wagers and markets are limited and/or blocked, alternative markets may be provided to user 210. The alternative markets may be provided based on the markets that were limited/blocked such that user 210 is provided with similar markets. For example, user may request a user-requested market comprising an over/under of 120 points. This market may be determined to provide a high payout or, based on the teams and the players, the simulations may indicate that there is a high amount of randomness in the total score output. Therefore, the wager may be limited. System 202 may notify user 210 that this market is not possible and provide an alternative market with an over/under of 115 points.

FIG. 5 depicts an exemplary flow chart illustrating method 500 for modifying pricing terms for a market. The steps illustrated here may be provided independently of FIGS. 4A-4C; however, in some embodiments, the steps of FIG. 5 may be provided with the methods illustrated in FIGS. 4A-4C. For example, modifying pricing terms for a market may be performed after step 410 of FIG. 4A, between step 420 and step 422 of FIG. 4B, and/or after step 432 of FIG. 4C. As such, modifying the pricing terms of a market may take place at least after the markets are provided to a user. In some embodiments, method 500 is performed in part or entirely by system 200 and/or pricing system 216.

In step 502, a request to modify a bet line is received. A modification of a bet line (e.g., market) is any action that may change the pricing terms associated with the bet line compared to the pricing terms currently being presented to the user. In some embodiments, a request is received to update one or more parameters of a bet line. For example, if a user has an active bet for team A scoring seven goals during a game and the user desires to update the bet line such that the user is betting on team A scoring eight goals during the game, a request to modify the bet line may be transmitted to a pricing system, such as pricing system 216. In some embodiments, a request is received to cash out on a bet line. For example, if a user wishes to cash out on an active bet before the natural termination of the bet, a request to cash out on the bet line may be transmitted to a pricing system. An active bet may be repriced to reflect changes to the outcome matrix currently being used to price markets compared to the outcome matrix used to price the active bet when it was first placed by a user.

In step 504, a query associated with the modified market is generated. As discussed with regard to FIG. 2C, a modified market request may be received by a query generator. Accordingly, the query generator may parse the parameters of the modified market and generate a query representing the modified market. For example, if a user wishes to bet on a player having 20 rushing yards during a game as opposed to 0 rushing yards during the game, the query generator may parse out the parameters of the player, the type of player proposition, the number of rushing yards, and the game. In such embodiments, the query generator may form a query, such as a query in a particular language, and transmit the query to a pricing engine. By generating a new query associated with the modified market, new queries can be generated for predefined markets that a user wishes to modify.

In step 506, the modified market is repriced based on the new query. As discussed above with regard to FIG. 2C, the pricing engine may interface with an outcome matrix, such as outcome matrix 232 created by simulation engine 224, in order to gather outcome information related to the parameters of the query. Subsequently, the pricing engine may calculate the probability of the modified market occurring. The calculated probability may then be used to price the modified market such that the modified market reflects the risk associated with the bet. Similarly, in regard to a modification in the form of a cashout, the probability may then be used to price the modified market to reflect the cost of exiting a market early.

In step 508, the terms of the modified market is presented to the user. For example, the user may be presented with a user interface listing the modified pricing terms for their requested modification. In such embodiments, the user interface may also provide an actuatable button (or other element) for the user to press if the user wishes to accept the new pricing terms and modify their original bet with the parameters of the modified market. For example, if a user requests to cash out, the user may be presented with the value of the cash out along with a UI element the user can press if they wish to cancel the cashout or proceed with the cashout.

In step 510, an acceptance of the modification is received. For example, as discussed in step 508, the acceptance may be received through an actuation of a UI element associated with an acceptance. Upon accepting the modification, one or more external systems may be interfaced with to initiate the modification. For example, a wallet system may be interfaced with to withdraw or deposit currency into an account of a user. For another example, an external system may be interfaced with to close out the bet and deposit or withdraw funds from the account of the user. Additionally, upon acceptance of the modification, the user interface presenting the bets to the user may be modified to reflect the modification.

Features described above as well as those claimed below may be combined in various ways without departing from the scope hereof. The following examples illustrate some possible, non-limiting combinations:

Clause 1. One or more non-transitory computer-readable media storing computer-executable instructions that, when executed by at least one processor, perform a method of pricing predefined and user-requested markets, the method comprising: receiving a market request, wherein the market request is for a predefined market; retrieving a query indicative of the predefined market; selecting, by the query, a set of outcome data from an outcome matrix and equations for pricing the predefined market; and pricing the predefined market based at least in part on the set of outcome data for pricing the predefined market.

Clause 2. The one or more non-transitory computer-readable media of clause 1, wherein the market request is received from a user computing device.

Clause 3. The one or more non-transitory computer-readable media of clause 1 or clause 2, wherein the query is retrieved from a query lookup table.

Clause 4. The one or more non-transitory computer-readable media of clause 1 or clause 3, wherein the method further comprises: causing display of the predefined market by the user computing device.

Clause 5. The one or more non-transitory computer-readable media of clause 1 or clause 4, wherein the method further comprises: generating the outcome matrix, the outcome matrix searchable by the query.

Clause 6. The one or more non-transitory computer-readable media of clause 1 or clause 5, wherein the method further comprises: receiving a second market request from the user computing device, the second market request for a user-selected market, wherein the market request is a first market request; and generating a second query associated with the user-selected market, wherein the query is a first query.

Clause 7. The one or more non-transitory computer-readable media of clause 1 or clause 6, wherein generating the second query associated with the user-selected market comprises: parsing one or more parameters of the user-selected market; and translating the one or more parameters into a standardized query language.

Clause 8. The one or more non-transitory computer-readable media of clause 1 or clause 7, wherein the method further comprises: receiving, from the user computing device, a cashout request associated with the predefined market; and generating a second query based on the cashout request and the predefined market, wherein the query is a first query and the first query differs from the second query.

Clause 9. The one or more non-transitory computer-readable media of clause 1 or clause 8, wherein the method further comprises: selecting, by the second query, a second set of outcome data from a second outcome matrix for repricing the predefined market; and repricing the predefined market based at least in part on the second set of outcome data for pricing the predefined market, wherein the outcome matrix is a first outcome matrix and the set of outcome data is a first set of outcome data, wherein the first outcome matrix differs from the second outcome matrix.

Clause 10. The one or more non-transitory computer-readable media of clause 1 or clause 9, wherein one or more events during a contest result in a difference between the first outcome matrix and the second outcome matrix.

Clause 11. A system for pricing predefined and user-requested markets, the system comprising: one or more non-transitory computer-readable media storing computer-executable instructions that, when executed by at least one processor, perform a method of pricing the predefined and user-requested markets, the method comprising: receiving a market request, wherein the market request is for a modification of a leg of a multi-leg parlay; determining if a query representing the modification of the leg of the multi-leg parlay exists in a query lookup table; responsive to the query existing, retrieving the query indicative of the leg of the multi-leg parlay, wherein the query is retrieved from the query lookup table; selecting, by the query, a set of outcome data from an outcome matrix for pricing the leg of the multi-leg parlay; and pricing the leg of the multi-leg parlay based at least in part on the outcome matrix for pricing the leg of the multi-leg parlay.

Clause 12. The system of clause 11, wherein the market request is received from a user computing device.

Clause 13. The system of clause 11 or clause 12, wherein the method comprises: causing display of the leg of the multi-leg parlay by the user computing device.

Clause 14. The system of any of clause 11 through clause 13, wherein the leg of the multi-leg parlay comprises a plurality of existing parameters; and wherein the market request for the modification of the leg of the multi-leg parlay is for a parameter modification of an existing parameter from the plurality of existing parameters.

Clause 15. The system of any of clause 11 through clause 14, wherein the method further comprises: regenerating the outcome matrix, the outcome matrix regenerated at a predetermined interval.

Clause 16. The system of any of clause 11 through clause 15, wherein the leg of the multi-leg parlay comprises a user-requested market.

Clause 17. The system of any of clause 11 through clause 16, wherein the method further comprises: regenerating the outcome matrix, the outcome matrix regenerated when an event during a contest occurs.

Clause 18. The system of any of clause 11 through clause 17, wherein the leg of the multi-leg parlay comprises a predefined market.

Clause 19. The system of any of clause 11 through clause 18, wherein the method further comprises: receiving a second market request from the user computing device, the second market request for a second modification of a second leg of the multi-leg parlay, wherein the market request is a first market request, the modification is a first modification, and the leg is a first leg; and generating a second query associated with the second leg, wherein the query is a first query.

Clause 20. A method for pricing predefined and user-requested markets, the method comprising: running a contest simulation comprising a plurality of simulations of a contest; storing outcome data in an outcome matrix, wherein the outcome data is indicative of probabilities of one or more live events occurring during the contest; receiving a market request associated with a market; selecting, by a query associated with the market request, a set of outcome data from the outcome matrix and equations for pricing the market; and pricing the market based at least in part on the set of outcome data for pricing the market.

Clause 21. The method of clause 20, wherein the market request is received from a user computing device.

Clause 22. The method of clause 20 or clause 21, further comprising: causing display of the market by the user computing device

Clause 23. The method of any of clause 20 through clause 22, wherein the market further comprises at least one market recommended to a user associated with the user computing device.

Clause 24. The method of any of clause 20 through clause 23, further comprising: determining whether the market request is for a user-requested market or a predefined market.

Clause 25. The method of any of clause 20 through clause 24, further comprising: responsive to determining the market request is for the user-requested market, generating the query associated with the market request.

Clause 26. The method of any of clause 20 through clause 25, responsive to determining the market request is for the predefined market, retrieving the query from a query lookup table.

Clause 27. The method of any of clause 20 through clause 26, wherein the query is written in a standardized query language.

Although the present disclosure has been described with reference to the embodiments illustrated in the attached drawing figures, it is noted that equivalents may be employed and substitutions made herein without departing from the scope of the present disclosure as recited in the claims.

Having thus described various embodiments, what is claimed as new and desired to be protected by Letters Patent includes the following:

1. One or more non-transitory computer-readable media storing computer-executable instructions that, when executed by at least one processor, perform a method of pricing predefined and user-requested markets, the method comprising:
receiving a market request from a user computing device, wherein the market request is for a predefined market;
retrieving a query indicative of the predefined market, wherein the query is retrieved from a query lookup table;
selecting, by the query, a set of outcome data from an outcome matrix and equations for pricing the predefined market;
pricing the predefined market based at least in part on the set of outcome data for pricing the predefined market; and
causing display of the predefined market by the user computing device.

2. The one or more non-transitory computer-readable media of claim 1,
wherein the method further comprises:
generating the outcome matrix, the outcome matrix searchable by the query.

3. The one or more non-transitory computer-readable media of claim 1,
wherein the method further comprises:
receiving a second market request from the user computing device, the second market request for a user-selected market, wherein the market request is a first market request; and
generating a second query associated with the user-selected market, wherein the query is a first query.

4. The one or more non-transitory computer-readable media of claim 3,
wherein generating the second query associated with the user-selected market comprises:
parsing one or more parameters of the user-selected market; and
translating the one or more parameters into a standardized query language.

5. The one or more non-transitory computer-readable media of claim 1,
wherein the method further comprises:
receiving, from the user computing device, a cashout request associated with the predefined market; and
generating a second query based on the cashout request and the predefined market, wherein the query is a first query and the first query differs from the second query.

6. The one or more non-transitory computer-readable media of claim 5,
wherein the method further comprises:
selecting, by the second query, a second set of outcome data from a second outcome matrix for repricing the predefined market; and
repricing the predefined market based at least in part on the second set of outcome data for pricing the predefined market,
wherein the outcome matrix is a first outcome matrix and the set of outcome data is a first set of outcome data,
wherein the first outcome matrix differs from the second outcome matrix.

7. The one or more non-transitory computer-readable media of claim 6,
wherein one or more events during a contest result in a difference between the first outcome matrix and the second outcome matrix.

8. A system for pricing predefined and user-requested markets, the system comprising:
one or more non-transitory computer-readable media storing computer-executable instructions that, when executed by at least one processor, perform a method of pricing the predefined and user-requested markets, the method comprising:
receiving a market request from a user computing device, wherein the market request is for a modification of a leg of a multi-leg parlay;
determining if a query representing the modification of the leg of the multi-leg parlay exists in a query lookup table;
responsive to the query existing, retrieving the query indicative of the leg of the multi-leg parlay, wherein the query is retrieved from the query lookup table;
selecting, by the query, a set of outcome data from an outcome matrix for pricing the leg of the multi-leg parlay;
pricing the leg of the multi-leg parlay based at least in part on the outcome matrix for pricing the leg of the multi-leg parlay; and
causing display of the leg of the multi-leg parlay by the user computing device.

9. The system of claim 8,
wherein the leg of the multi-leg parlay comprises a plurality of existing parameters; and
wherein the market request for the modification of the leg of the multi-leg parlay is for a parameter modification of an existing parameter from the plurality of existing parameters.

10. The system of claim 8,
wherein the method further comprises:
regenerating the outcome matrix, the outcome matrix regenerated at a predetermined interval.

11. The system of claim 8,
wherein the leg of the multi-leg parlay comprises a user-requested market.

12. The system of claim 8,
wherein the method further comprises:
regenerating the outcome matrix, the outcome matrix regenerated when an event during a contest occurs.

13. The system of claim 8,
wherein the leg of the multi-leg parlay comprises a predefined market.

14. The system of claim 13,
wherein the method further comprises:
receiving a second market request from the user computing device, the second market request for a second modification of a second leg of the multi-leg parlay, wherein the market request is a first market request, the modification is a first modification, and the leg is a first leg; and
generating a second query associated with the second leg, wherein the query is a first query.

15. A method for pricing predefined and user-requested markets, the method comprising:
running a contest simulation comprising a plurality of simulations of a contest;
storing outcome data in an outcome matrix,
wherein the outcome data is indicative of probabilities of one or more live events occurring during the contest;
receiving a market request associated with a market from a user computing device;
selecting, by a query associated with the market request, a set of outcome data from the outcome matrix and equations for pricing the market;
pricing the market based at least in part on the set of outcome data for pricing the market; and
causing display of the market by the user computing device.

16. The method of claim 15,
wherein the market further comprises at least one market recommended to a user associated with the user computing device.

17. The method of claim 15, further comprising:
determining whether the market request is for a user-requested market or a predefined market.

18. The method of claim 17, further comprising:
responsive to determining the market request is for the user-requested market, generating the query associated with the market request.

19. The method of claim 17,
responsive to determining the market request is for the predefined market, retrieving the query from a query lookup table.

20. The method of claim 15,
wherein the query is written in a standardized query language.
